(19) United States
(12) Patent Application Publication
(10) Pub. No.: US 2005/0133904 A1
(43) Pub. Date: Jun. 23, 2005

(54) Method of forming metal pattern for hermetic sealing of package

(75) Inventors: Jin Young Kim, Gyeonggi-Do (KR); Won Kyoung Choi, Gyeonggi-Do (KR); Chang Ho Noh, Gyeonggi-Do (KR); Ki Yong Song, Seoul (KR)

Correspondence Address: BURNS DOANE SWECKER & MATHIS L L P, POST OFFICE BOX 1404, ALEXANDRIA, VA, 22313-1404, US

(73) Assignee: Samsung Electronics Co., Ltd., Gyeonggi-do (KR)

(21) Appl. No.: 10/990,984

(22) Filed: Nov. 18, 2004

(30) Foreign Application Priority Data
Nov. 20, 2003 (KR) 2003-82597

(51) Int. Cl. H01L 21/48; H01L 23/552

(52) U.S. Cl. 257/704; 438/125; 257/659; 257/660

(57) ABSTRACT

A method of forming a metal multilayer pattern for hermetic sealing of a package. According to the method, a metal multilayer pattern for hermetic sealing of a package is formed by forming latent image centers for crystal growth using a photocatalytic compound, followed by plating the latent pattern. The method avoids the use of vacuum deposition processes, e.g., sputtering and evaporation, requiring vacuum conditions. In addition, the method does not involve a photolithographic process for the formation of the metal multilayer pattern. Accordingly, the metal multilayer pattern for hermetic sealing of a package can be formed in a simple and economical manner.

### BACKGROUND OF THE INVENTION

This non-provisional application claims priority under 35 U.S.C. § 119(a) on Korean Patent Application No. 2003-82597 filed on Nov. 20, 2003, which is herein expressly incorporated by reference.

A. Field of the Invention

The present invention relates to a method of forming a metal multilayer pattern for hermetic sealing of a package, and more particularly to a method of forming a metal multilayer pattern for hermetic sealing of a package by forming a latent pattern of latent image centers for crystal growth using a photocatalytic compound, followed by plating the latent pattern.

B. Description of the Related Art

Upon packaging an electronic or photonic device, a hermetic sealing process is required to prevent moisture from entering the device and adhering to the device, to prevent oxidation of the device, and to maintain the internal atmosphere of the device, thus improving the reliability of the device. According to a conventional hermetic sealing process, a low melting point glass frit is placed on a region to be joined, and heated to seal the region. However, problems associated with the conventional process are that gases exhausted during the process contaminate a package device and a package lid, deteriorating the characteristics of the device. A currently used hermetic sealing process is performed by forming a metal layer between a package lid and a package device through soldering, thereby housing the device in the package. The metal layer to be soldered is formed by forming a metal layer on the package lid, followed by etching the metal layer to create a frame suited to the lid. At this time, the metal layer is formed by forming a metal seed layer using a vacuum deposition apparatus (e.g., sputtering, evaporation, or enhanced ion-plating (EIP) apparatus) in a high-vacuum chamber, followed by vacuum deposition or electroplating of the metal seed layer. Thus, the process necessitates the use of an expensive high-vacuum apparatus, incurring considerable production costs. In addition, since a photoresist is used to form a pattern, etching is necessary and thus the process is complicated. Furthermore, residues remaining on the surface of a glass substrate may contaminate the device, deteriorating the characteristics of the device and hermeticity of the package.

### SUMMARY OF THE INVENTION

Therefore, the present invention has been made in view of the above problems, and it is an object of the present invention to provide a method of forming a metal multilayer pattern for hermetic sealing of a package in a simple manner, without the use of a vacuum deposition apparatus, e.g., sputtering or evaporation apparatus requiring vacuum conditions for the formation of a conductive metal thin film, and without involving a photolithographic process for the formation of the metal multilayer pattern.

In accordance with one embodiment of the present invention, there is provided a method of forming a metal multilayer pattern for hermetic sealing of a package, comprising the steps of: (i) coating a photocatalytic compound on a substrate to form a photocatalytic film, and selectively exposing the photocatalytic film to light to form a latent pattern of latent image centers for crystal growth; (ii) growing metal crystals on the latent image centers by plating to form a patterned metal seed layer; and (iii) forming at least one metal layer on the metal seed layer by plating.

In accordance with another embodiment of the present invention, there is provided a metal multilayer pattern for hermetic sealing formed by the method.

### BRIEF DESCRIPTION OF THE DRAWINGS

The above and other objects, features and other advantages of the present invention will be more clearly understood from the following detailed description taken in conjunction with the accompanying drawings, in which:

FIG. 1 shows the Auger electron spectroscopy (AES) depth profile of the elements present in the metal layers of a metal multilayer pattern formed in Example 5 of the present invention; and

FIGS. 2a to 2c are optical micrographs of metal multilayer patterns formed in Example of the present invention.

FIG. 3 shows a schematic diagram of a hermetic seal with exemplary layers illustrated.

### DESCRIPTION OF THE PREFERRED EMBODIMENTS

Hereinafter, the present invention will be explained in more detail, based on the respective steps.

Step (i):

First, a photocatalytic compound is coated on a substrate to form a photocatalytic film. The photocatalytic film is then selectively exposed to light to form a latent pattern comprising active portions and inactive portions. The latent pattern plays a role as a pattern of latent image centers for crystal growth in a subsequent plating step.

The term “photocatalytic compound” as used herein refers to a compound whose characteristics are changed by light. Some photocatalytic compounds (a) are inactive when not exposed to light, but their reactivity is accelerated upon being exposed to light, e.g., UV light. Alternatively, some photocatalytic compounds (b) are active when not exposed to light, but their reactivity is lost upon exposure to light, e.g., UV light, and eventually they become inactive. The photocatalytic compounds (a) are those electron-excited by photoreaction upon light exposure, thus exhibiting a reducing ability. Accordingly, reduction of metal ions in the exposed portion takes place, and thus a negative-type latent pattern can be formed. Preferred examples of the photocatalytic compounds (a) are Ti-containing organometallic compounds which can form TiOₓ (in which x is a number not higher than 2) upon exposure to light.

Examples of suitable Ti-contig organometallic compounds include tetraisopropyl titanate, tetra-n-butyl titanate, tetrakis(2-ethyl-hexyl) titanate and polybutyl titanate. Meanwhile, the photocatalytic compounds (b) are those oxidized by photoreaction upon light exposure, thus losing their activity in the exposed portion. The activity of the photocatalytic compounds (b) is maintained only in the unexposed portion, where reduction of metal ions takes place and thus a positive-type latent pattern can be formed. Preferred examples of the photocatalytic compounds are Sn-containing organometallic compounds. Examples of suitable Sn-containing organometallic compounds include SnCl(OH) and SnCl₂.

Following dissolving the photocatalytic compound in an appropriate solvent, e.g., isopropyl alcohol, the solution can be coated on a substrate by spin coating, spray coating, screen printing or the like.

Examples of substrates usable in the present invention preferably include, but are not specially limited to, transparent plastic and glass. As examples of the transparent plastic substrate, acrylic resins, polyesters, polycarbonates, polyethylenes, polyethersulfones, olefin maleimide copolymers, norbornene-based resins, etc. can be mentioned. In the case where excellent heat resistance is required, olefin maleimide copolymers and norbornene-based resins are preferred. Otherwise, it is preferred to use polyester films, acrylic resins or the like.

Exposure atmospheres and exposure doses under which the photocatalytic film is exposed are not especially limited, and can be properly selected according to the kind of the photocatalytic compound used.

In this step, if necessary, the latent image centers for crystal growth may be treated with a metal salt solution to form a metal particle-deposited pattern thereon, in order to effectively form a denser metal pattern in the subsequent step (ii). The deposited metal particles play a role as catalysts accelerating growth of metal crystals in the subsequent plating step. When the pattern is plated with copper, nickel or gold, treatment with the metal salt solution is preferred. As the metal salt solution, Ag salt solution, Pd salt solution or a mixed solution thereof is preferably used.

Step (ii):

The latent pattern acting as a nucleus for crystal growth formed in step (i), or the metal particle-deposited pattern, is subjected to plating to grow metal crystals on the pattern of nucleus for crystal growth, thereby forming a patterned metal seed layer. The plating is performed by an electroless or electroplating process. In the case of the metal particle-deposited pattern formed by treating the latent pattern with a metal salt solution, since the metal particles exhibit sufficient activity as catalysts in an electroless plating solution, crystal growth is accelerated and thus a more densely packed metal pattern can be formed.

The choice of suitable plating metals for use in the present invention is determined according to the kind of the substrate and treatment conditions employed. The plating metal is preferably selected from the group consisting of Cu, Ni, Pd, Pt and alloys thereof

The electroless or electroplating is achieved in accordance with well-known procedures. According to a common electroless plating process, the substrate on which the latent image centers for crystal growth are formed is immersed in a plating solution having a composition comprising (1) a metal salt, (2) a reducing agent, (3) a complexing agent, (4) a pH-adjusting agent, (5) a pH buffer, and (6) a modifying agent. The metal salt (1) serves as a source providing the substrate with metal ions. Examples of the metal salt include chlorides, sulfates and cyanides of the metal. The reducing agent (2) acts to reduce metal ions present on the substrate. Specific examples of the reducing agent include NaBH₄, KBH₄, NaH₂PO₂, hydrazine, formaline and polysaccharides (e.g., glucose). Formaline and polysaccharides (e.g., glucose) are preferred. The complexing agent (3) functions to prevent the precipitation of hydroxides in an alkaline solution and to control the concentration of free metal ions, thereby preventing the decomposition of the metal salts and adjusting the plating speed. Specific examples of the complexing agent include ammonia solution, acetic acid, guanine acid, tartaric acid, chelating agents (e.g., EDTA), and organic amine compounds. Chelating agents (e.g., EDTA) are preferred. The pH-adjusting agent (4) serves to adjust the pH of the plating solution, and is selected from acidic or basic compounds. The pH buffer (5) inhibits the sudden change in the pH of the plating solution, and is selected from organic acids and weakly acidic inorganic compounds. The modifying agent (6) is a compound capable of improving coating and planarization characteristics. Specific examples of the modifying agent include common surfactants, and adsorptive substances capable of adsorbing components which interfere with the crystal growth.

The plating solution for electroless plating may further contain other stabilizers, such as a plating promoter and stabilizer, according to the kind of the metal salt The plating promoter used in a slight amount not only accelerates the plating speed, but also inhibits the evolution of hydrogen gas to increase the metal precipitation efficiency. Representative examples of the plating promoter are sulfides and fluorides.

The stabilizer serves to prevent a reduction reaction from taking place at positions other than the surface to be plated. That is, the stabilizer prevents natural decomposition of the plating solution and vigorous evolution of hydrogen gas, which results from a reaction between the reducing agent and precipitates generated from aging of the plating solution.

A plating solution for an electroplating process has a composition comprising (1) a metal salt, (2) a complexing agent, (3) a pH-adjusting agent, (4) a pH buffer, and 5) a modifying agent. The functions and the specific examples of the components contained in the plating solution are as defined in the electroless-plating process.

Step (iii):

In this step, the metal seed layer formed in step (ii) is subjected to electroless or electroplating to form a plurality of metal layers thereon, thereby forming the final metal multilayer pattern for hermetic sealing of a package.

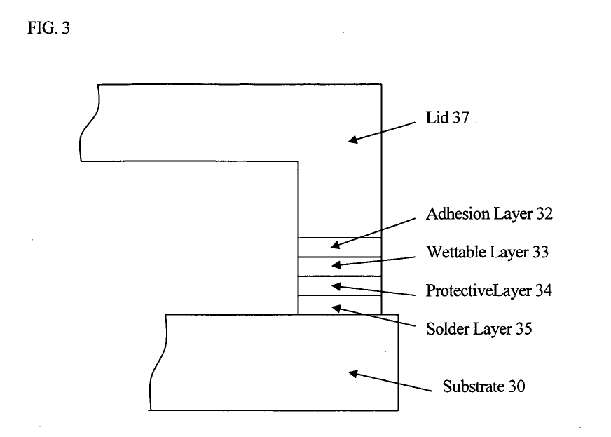

As schematically demonstrated in FIG. 3, a commonly used metal multilayer pattern for hermetic sealing between a substrate 30 and a lid 37 may have a multilayer structure comprising an adhesion layer 32, a wettable layer 33, a protective layer 34, and a solder layer 35. The adhesion layer 32 is provided for better adherence to a substrate 30, the wettable layer 33 is provided to improve the wettability of the metal, the protective layer 34 is provided to prevent the metal from being contaminated by external sources, and the solder layer 35 is composed of a low melting point metal. However, the present invention is not restricted to this multilayer structure, and any metal multilayers that can be anticipated from the prior art can be employed in the present invention. Exemplary metals for the respective layers are listed in Table 1 below.

TABLE 1

| | |
|---|---|
| Adhesion layer | Cr, Ti, TiW alloy |
| Wettable layer | Ni, Cu, Pd, Pt, Cu/Ni, CrCu alloy, CuNi alloy |
| Protective layer | Noble metals, such as Au, Pt, Ag, etc. |
| Solder layer | Sn or Sn-based multi-element alloys such as AuSn, SnSb, |
| | SnAg, SnPb, SnBi, SnIn, etc. |

When comparing the structure of this common metal multilayer pattern with that of the metal multilayer pattern for hermetic sealing formed by an embodiment of the method of the present invention, the wettable layer corresponds to the seed layer formed in the present invention. Further, since the pattern of the photocatalytic compound formed in the present invention can function as the adhesion layer, the formation of a separate adhesion layer can be omitted in the present invention.

The present invention will now be described in more detail with reference to the following preferred examples. However, these examples are given for the purpose of illustration and are not to be construed as limiting the scope of the invention.

### FORMATION EXAMPLE 1

### Formation of a Pattern of a Photocatalytic Compound for Formation of a Negative-Type Metal Pattern

After a solution of 2.5˜5 wt % of polybutyl titanate in butanol was spin-coated on a soda-lime glass substrate, the coated substrate was heat-treated at 150° C. for 15 minutes. UV light having a broad wavelength range was irrdiated to the substrate through a photomask on which a minute mesh pattern was formed using a UV exposure system (Oriel, U.S.A.). After exposure, the substrate was immersed in an active catalyst solution of PdCl₂ (0.6 g) and HCl (1 mL) in water (1 L) to deposit Pd particles on the exposed portion.

### FORMATION EXAMPLE 2

### Formation of a Pattern of a Photocatalytic Compound for Formation of a Positive-Type Metal Pattern

First, 22 g of SnCl₂ was dissolved in 1 L of water, and then 10 mL of hydrochloric acid was added thereto to obtain a solution. After a soda-lime glass substrate was immersed in the solution for 1 minute, the resulting substrate was dried at 100° C. for 2 minutes to form a photocatalytic compound-coated substrate having a thickness of 50 nm or less. UV light having a broad wavelength range was irradiated to the substrate through a photomask on which a minute mesh pattern was formed using a UV exposure system (Oriel, U.S.A.). After exposure, the substrate was immersed in an active catalyst solution of PdCl₂ (0.6 g) and HCl (1 mL) in water (1 L) to deposit Pd particles on the unexposed portion.

### EXAMPLE 1

### Formation of a Negative-Type Nickel Seed Layer by Electroless Nickel Plating

Two substrates prepared by the method of Formation Example 1 were immersed in an electroless nickel plating solution to selectively grow crystals of nickel wires thereon. The electroless nickel plating solution used herein was prepared so as to have the composition indicated in (a) of Table 2 below.

The basic physical properties of the nickel layers on the two substrates are shown in Table 3 below. The thickness of the nickel layers was measured using alpha-step (manufactured by Dektak), the resolution was determined using an optical microscope, and the adhesive force was evaluated by a scotch tape peeling test.

### EXAMPLE 2

### Formation of a Negative-Type Copper Seed Layer by Electroless Copper Plating

Two substrates prepared by the method of Formation Example 1 were immersed in an electroless copper plating solution to selectively grow crystals of copper wires thereon. The electroless copper plating solution used herein was prepared so as to have the composition indicated in (b) of Table 2 below.

The basic physical properties of the copper layers on the two substrates are shown in Table 4 below. The thickness of the copper layers was measured using alpha-step (manufactured by Dektak) and the specific resistance was measured using a 4-point probe. The resolution was determined using an optical microscope and the adhesive force was evaluated by a scotch tape peeling test.

### EXAMPLE 3

### Formation of a Positive-Type Nickel Seed Layer by Electroless Nickel Plating

Two substrates prepared by the method of Formation Example 2 were immersed in an electroless nickel plating solution to selectively grow nickel crystals thereon. The electroless nickel plating solution used herein was prepared so as to have the composition indicated in (a) of Table 2 below.

The basic physical properties of the nickel layers on the two substrates are shown in Table 3 below. The thickness of the nickel layers was measured using alpha-step (manufactured by Dektak), the resolution was determined using an optical microscope, and the adhesive force was evaluated by a scotch tape peeling test.

### EXAMPLE 4

### Formation of a Positive-Type Copper Seed Layer by Electroless Copper Plating

Two substrates prepared by the method of Formation Example 2 were immersed in an electroless copper plating solution to selectively grow copper crystals thereon. The electroless copper plating solution used herein was prepared so as to have the composition indicated in (b) of Table 2 below.

The basic physical properties of the copper layers on the two substrates are shown in Table 4 below. The thickness of the copper layers was measured using alpha-step (manufactured by Dektak) and the specific resistance was measured using a 4-point probe. The resolution was determined using an optical microscope and the adhesive force was evaluated by a scotch tape peeling test.

TABLE 2

| (a) Electroless nickel | (b) Electroless copper |
|---|---|
| plating solution (g/L) | plating solution (g/L) |
| Nickel chloride 44 | Copper sulfate 3.5 |
| Sodium hypophosphite 11 | Rochelle salt 8.5 |
| Sodium citrate 100 | Formaline (37%) 22 mL |
| Ammonium chloride 50 | Thiourea 1 |
| Deionized water 11 | Ammonia 40 |
| pH: 8.5˜9.5 | Deionized water 11 |
| Temperature: 90˜100° C. | Temperature 35° C. |
| Plating speed: 15 μm/hr. | |

TABLE 3

| Example No. | Film thickness (Å) | Resolution (μm) | Adhesive force |
|---|---|---|---|
| Example 1 | 1725 | <5 | Good |
| Example 1 | 2396 | <5 | Good |
| Example 3 | 747 | <5 | Good |
| Example 3 | 1000 | <5 | Good |

TABLE 4

| | Film | Specific resistance | Resolution | Adhesive |
|---|---|---|---|---|
| Example No. | thickness (Å) | (μohm-cm) | (μm) | force |
| Example 2 | 2865 | 2.7 | <5 | Good |
| Example 2 | 2517 | 2.3 | <5 | Good |
| Example 4 | 2680 | 3.1 | <5 | Good |
| Example 4 | 2650 | 2.6 | <5 | Good |

### EXAMPLE 5

### Formation of a Metal Multilayer Pattern by Plating Additional Metals on a Substrate Treated by Selective Electroless Metal Plating

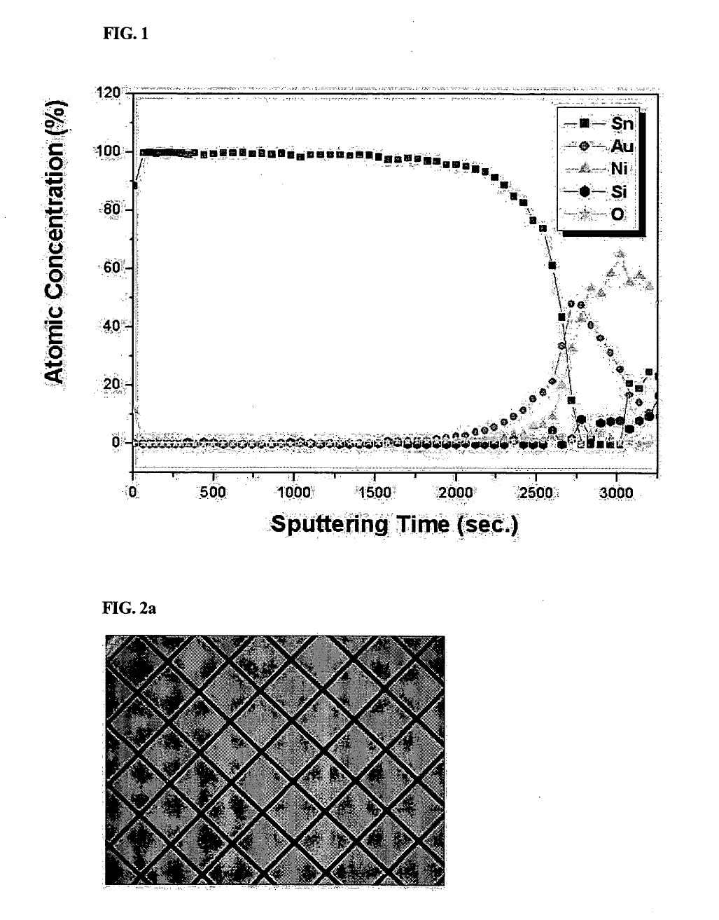

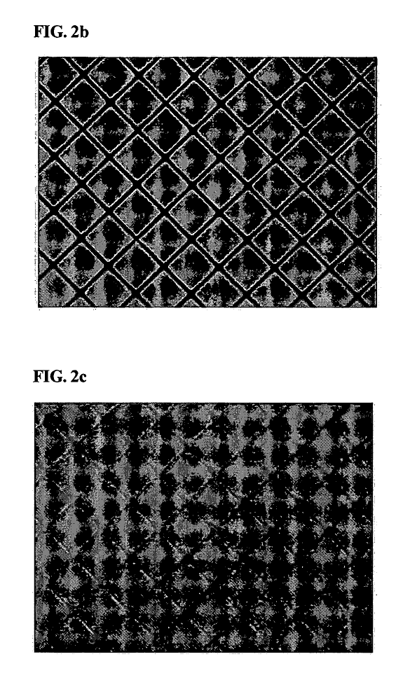

A substrate prepared by the method of Formation Example 1 was first immersed in an electroless nickel plating solution to selectively grow crystals of a nickel wire thereon. Then, the substrate was immersed in electroless gold and tin plating solutions to selectively grow crystals of gold and silver, respectively, thereon. The electroless nickel plating solution used herein was prepared so as to have the composition indicated in (a) of Table 2 above. The electroless Au and Sn plating solutions used herein were prepared so as to have the compositions indicated in (a) and (b) of Table 5 below, respectively. The nickel seed layer was subjected to electroless plating in the same manner as the electroless nickel plating to form a metal multilayer pattern comprising Ni-Au-Sn. After formation of the metal multilayer pattern, elemental analysis of the metal layers was performed by depth profiling analysis via Auger electron spectroscopy (AES), and the results are shown in FIG. 1. The difference in the resolution according to the components constituting the metal layers was observed under an optical microscope. The micrographs are shown in FIGS. 2a to 2c. FIGS. 2a to 2c are optical micrographs taken after formation of the Ni layer (FIG. 2a), the Au layer (FIG. 2b), and the Sn layer (FIG. 2c), respectively.

TABLE 5

| (a) Electroless | (b) Electroless tin plating |
|---|---|
| gold plating solution (g/L) | solution (mol/L) |
| Gold potassium cyanide 2 | Na₃ citrate.2H₂O 0.2˜0.5 |
| Ammonium chloride 50 | Na₂ EDTA 0.01˜0.16 |
| pH: 7˜7.5 | Sn²⁺ (added as sulfonate) 0.008˜0.13 |
| Temperature: 92˜95° C. | Na₃ NTA 0˜0.20 |
| Plating speed: 4.7 μm/hr. | Ti³⁺ (added as sulfonate) 0.01˜0.07 |
| | pH: 6.5˜9.5 |
| | Temperature: 80° C. |

As apparent from the above description, the present invention provides an effective method of forming a high resolution metal multilayer pattern for hermetic sealing within a short time by forming a photocatalytic thin film on a substrate by a simple coating process, followed by selective plating of the thin film. The method of the present invention avoids the use of conventional thin film deposition processes, e.g., sputtering, evaporation, photopatterning using photosensitive resins and etching processes requiring vacuum conditions. In addition, metal multilayer patterns formed by the method of the present invention not only exhibit performances comparable to those formed by conventional methods, but also can be formed in a relatively simple manner at a relatively low cost.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A method of forming a metal mutilayer pattern for hermetic sealing of a package, comprising the steps of:
(i) coating a photocatalytic compound on a substrate to form a photocatalytic film, and selectively exposing the photocatalytic film to light to form a latent pattern of latent image centers for crystal growth;
(ii) growing metal crystals on the latent image centers by plating to form a patterned metal seed layer; and
(iii) forming at least one metal layer on the metal seed layer by plating.

2. The method according to claim 1, further comprising the step of treating the latent pattern formed in step (i) with a metal salt solution to form a metal particle-deposited pattern thereon.

3. The method according to claim 2, wherein the metal salt solution is palladium salt solution, silver salt solution, or a mixed solution thereof.

4. The method according to claim 1, wherein the photocatalytic compound is a compound having inactivity when not exposed to light, but electron-excited by photoreaction upon light exposure, thus exhibiting a reducing ability.

5. The method according to claim 4, wherein the compound exhibiting a reducing ability by photoreaction is a Ti-containing organometallic compound which forms TiOₓ (in which x is a number not higher than 2) upon exposure to light.

6. The method according to claim 5, wherein the Ti-containing organometallic compound is selected from the group consisting of tetraisopropyl titanate, tetra-n-butyl titanate, tetrakis(2-ethyl-hexyl) titanate and polybutyl titanate.

7. The method according to claim 1, wherein the photocatalytic compound is a compound having activity when not exposed to light, but oxidized by photoreaction upon light exposure, thus losing its activity.

8. The method according to claim 7, wherein the compound losing its activity by photoreaction is a Sn-containing organometallic compound.

9. The method according to claim 8, wherein the Sn-containing organometallic compound is SnCl(OH) or SnCl₂.

10. The method according to claim 1, wherein the plating in steps (ii) and (iii) is performed by an electroless or electroplating process.

11. The method according to claim 1, wherein the plating in step (ii) is performed with a plating metal selected from the group consisting of Cu, Ni, Pd, Pt, Cr and alloys thereof.

12. A method of hermetic sealing comprising:
providing an adhesion layer on a substrate, providing a wettable layer on the adhesion layer, said wetting layer being formed in accordance with the method of claim 1,
providing a protective layer on the wettable layer, and
providing a solder layer on the protective layer, said solder layer composed of a low melting point metal.

13. A metal multilayer pattern for hermetic sealing formed by:
(i) coating a photocatalytic compound on a substrate to form a photocatalytic film, and selectively exposing the photocatalytic film to light to form a latent pattern of latent image centers for crystal growth;
(ii) growing metal crystals on the latent image centers by plating to form a patterned metal seed layer; and
(iii) forming at least one metal layer on the metal seed layer by plating.
